(19) United States
(12) Patent Application Publication
(10) Pub. No.: US 2024/0030246 A1
(43) Pub. Date: Jan. 25, 2024

(54) IMAGING DEVICE AND ELECTRONIC DEVICE

(71) Applicant: SONY SEMICONDUCTOR SOLUTIONS CORPORATION, Kanagawa (JP)

(72) Inventor: Hiroaki MURAKAMI, Kanagawa (JP)

(73) Assignee: SONY SEMICONDUCTOR SOLUTIONS CORPORATION, Kanagawa (JP)

(21) Appl. No.: 18/256,901

(22) PCT Filed: Nov. 11, 2021
(86) PCT No.: PCT/JP2021/041467

§ 371 Date: Jun. 9, 2023

(30) Foreign Application Priority Data
Dec. 21, 2020 (JP) 2020-211800

(51) Int. Cl. H01L 27/146

(52) U.S. Cl. CPC H01L 27/14612; H01L 27/14643; H01L 27/14603

(57) ABSTRACT

Provided are an imaging device and an electronic device capable of improving the charge transfer characteristic. The imaging device includes a semiconductor substrate and a vertical transistor provided on the semiconductor substrate. The semiconductor substrate is provided with a hole opened to the first main surface side. The vertical transistor includes a first gate electrode provided inside the hole, and a second gate electrode provided outside the hole and connected to the first gate electrode. The first gate electrode includes a first part and a second part including a material having conductivity different from conductivity of the first part.

### TECHNICAL FIELD

The present disclosure relates to an imaging device and an electronic device.

### BACKGROUND ART

A CMOS image sensor is known as an imaging device including a photodiode and a transistor that reads out charge photoelectrically converted by the photodiode. Furthermore, in order to increase the saturation signal amount of the photodiode in the CMOS image sensor, it is known to use a vertical transistor as a transfer transistor for transferring charge from the photodiode to the floating diffusion (see Patent Document 1, for example). A vertical transistor includes a hole formed in a semiconductor substrate, a gate insulating film formed in a state of covering an inner wall of the hole, and a vertical gate electrode formed in a state of filling the hole with the gate insulating film interposed therebetween.

### CITATION LIST

### Patent Document

Patent Document 1: Japanese Patent Application Laid-Open No. 2013-26264

### SUMMARY OF THE INVENTION

### Problems to be Solved by the Invention

The vertical gate electrode is long in the depth direction from the surface of the semiconductor substrate. For this reason, in the transfer transistor having the vertical gate electrode, the transfer path of charge is long in the depth direction of the semiconductor substrate, and when the gate of the transfer transistor is switched from on to off, charge in the middle of transfer tends to easily return to the photodiode side (i.e., charge is easily pumped up). When charge is pumped up, there is a possibility that the charge transfer characteristic of the transfer transistor is deteriorated.

The present disclosure has been made in view of such circumstances, and an object thereof is to provide an imaging device and an electronic device capable of improving the charge transfer characteristic.

### Solutions to Problems

An imaging device according to one aspect of the present disclosure includes a semiconductor substrate and a vertical transistor provided on the semiconductor substrate. The semiconductor substrate is provided with a hole opened to the first main surface side. The vertical transistor includes a first gate electrode provided inside the hole, and a second gate electrode provided outside the hole and connected to the first gate electrode. The first gate electrode includes a first part and a second part including a material having conductivity different from conductivity of the first part.

According to this, it is possible to provide a difference in conductivity between the first part and the second part, and it is possible to vary the potential gradient of a channel region (i.e., charge transfer path) formed in the semiconductor substrate. Even in a case where the charge transfer path is long in the longitudinal direction like a vertical transistor, it is possible to curb pumping up of the charge by varying the potential gradient of the transfer path, and it is possible to improve the charge transfer characteristic.

An electronic device according to one aspect of the present disclosure includes an optical component, the imaging device on which light transmitted through the optical component is incident, and a signal processing circuit that processes a signal output from the imaging device. According to this, since it is possible to improve the charge transfer characteristic in the imaging device, it is possible to improve the performance of the electronic device.

### BRIEF DESCRIPTION OF DRAWINGS

FIG. 1 is a diagram illustrating a configuration example of an imaging device according to First Embodiment of the present disclosure.

FIG. 2 is a plan view illustrating one example of a pixel sharing structure of the imaging device according to First Embodiment of the present disclosure.

FIG. 3 is a plan view illustrating a configuration example of a pixel according to First Embodiment of the present disclosure.

FIG. 4 is a cross-sectional view illustrating a configuration example of the pixel according to First Embodiment of the present disclosure.

FIG. 5 is a graph schematically illustrating a potential distribution in a charge transfer path when a transfer transistor is in an on state.

FIG. 6 is a cross-sectional view illustrating a configuration example of a pixel according to Second Embodiment of the present disclosure.

FIG. 7 is a cross-sectional view illustrating a configuration example of a pixel according to Third Embodiment of the present disclosure.

FIG. 8 is a cross-sectional view illustrating a configuration example of a pixel according to Fourth Embodiment of the present disclosure.

FIG. 9 is a cross-sectional view illustrating a configuration example of a pixel according to Fifth Embodiment of the present disclosure.

FIG. 10 is a cross-sectional view illustrating a configuration example of a pixel according to Sixth Embodiment of the present disclosure.

FIG. 11 is a block diagram illustrating a configuration example of an imaging device mounted on an electronic device.

FIG. 12 is a diagram illustrating one example of a schematic configuration of an endoscopic surgery system to which the technology according to the present disclosure (present technology) can be applied.

FIG. 13 is a block diagram illustrating one example of a functional configuration of a camera head and a CCU illustrated in FIG. 12.

FIG. 14 is a block diagram 14 illustrating a schematic configuration example of a vehicle control system which is one example of a movable body control system to which the technology according to the present disclosure can be applied.

FIG. 15 is a diagram illustrating an example of an installation position of an imaging section.

### MODES FOR CARRYING OUT THE INVENTION

Hereinafter, embodiments of the present disclosure will be described with reference to the drawings. In the description of the drawings referred to in the following description, the same or similar parts are denoted by the same or similar reference numerals. Note, however, that the drawings are schematic, and the relationship between the thickness and the plane dimension, the ratio of the thickness of each layer, and the like are different from actual ones. Therefore, specific thicknesses and dimensions should be determined in consideration of the following description. Furthermore, it is needless to say that dimensional relationships and ratios may differ among the drawings.

The definition of directions such as up and down in the following description is merely a definition for convenience of description, and does not limit the technical idea of the present disclosure. For example, it is a matter of course that when an object is observed by rotating the object by 90 degrees, the upper and lower sides are converted into left and right, and when the object is observed by rotating the object by 180 degrees, the upper and lower sides are inverted.

The following description uses an example of a case where the first conductivity type is the N-type and the second conductivity type is the P-type. However, the conductivity type may be reversed, and the first conductivity type may be the P-type and the second conductivity type may be the N-type. Furthermore, + or − added to N or P represents a semiconductor region having a relatively high or low impurity concentration as compared with a semiconductor region in which + or − is not added. Note, however, that even if semiconductor regions are denoted with the same symbol “N” (or the same symbol “P”), it does not mean that the semiconductor regions have exactly the same impurity concentrations.

### First Embodiment

(Overall Configuration Example)

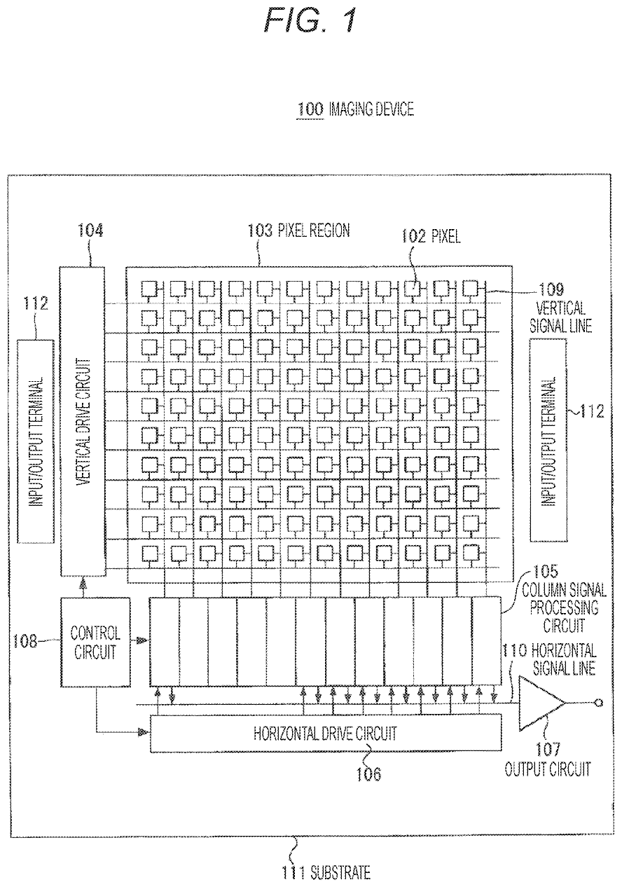

FIG. 1 is a diagram illustrating a configuration example of an imaging device 100 according to First Embodiment of the present disclosure. The imaging device 100 illustrated in FIG. 1 is, for example, a CMOS solid-state imaging device. As illustrated in FIG. 1, the imaging device 100 includes a pixel region (so-called imaging region) 103 in which a plurality of pixels 102 including a photoelectric conversion element is regularly and two-dimensionally arranged on a semiconductor substrate 111 (e.g., silicon substrate), and a peripheral circuit unit. The pixel 102 includes a photodiode serving as the photoelectric conversion element, and a plurality of pixel transistors (so-called MOS transistors). The plurality of pixel transistors can include three transistors including a transfer transistor, a reset transistor, and an amplification transistor. The plurality of pixel transistors can include four transistors by adding a selection transistor to the above three transistors. Since the equivalent circuit of the unit pixel is similar to a normal circuit, a detailed description thereof will be omitted.

The pixel 102 can have a shared pixel structure. The shared pixel structure includes a plurality of photodiodes, a plurality of transfer transistors, one shared floating diffusion, and one each of other shared pixel transistors. That is, in a shared pixel structure, photodiodes and transfer transistors included in a plurality of unit pixels share one each of pixel transistors other than the transfer transistor.

The peripheral circuit unit includes a vertical drive circuit 104, a column signal processing circuit 105, a horizontal drive circuit 106, an output circuit 107, a control circuit 108, and the like.

The control circuit 108 receives an input clock and data instructing an operation mode and the like, and outputs data such as internal information of the imaging device. That is, the control circuit 108 generates a clock signal and a control signal, which serve as a reference for the operations of the vertical drive circuit 104, the column signal processing circuit 105, the horizontal drive circuit 106, and the like, on the basis of a vertical synchronization signal, a horizontal synchronization signal, and a master clock. Then, the control circuit 108 inputs these signals to the vertical drive circuit 104, the column signal processing circuit 105, the horizontal drive circuit 106, and the like.

The vertical drive circuit 104 includes a shift register, for example, selects a pixel drive wiring, supplies a pulse for driving the pixel to the selected pixel drive wiring, and drives the pixels in row units. That is, the vertical drive circuit 104 selectively scans the pixels 102 of the pixel region 103 in row units sequentially in the vertical direction, and supplies the column signal processing circuit 105 with a pixel signal based on a signal charge generated according to the amount of received light in the photoelectric conversion element of each pixel 102 through a vertical signal line 109.

The column signal processing circuit 105 is arranged for each column of the pixels 102, for example, and performs signal processing such as noise removal on signals output from the pixels 102 for one row for each pixel column. That is, the column signal processing circuit 105 performs signal processing such as CDS for removing fixed pattern noise unique to the pixel 102, signal amplification, and AD conversion. A horizontal selection switch (not illustrated) is provided at an output stage of the column signal processing circuit 105 so as to be connected between the column signal processing circuit 105 and a horizontal signal line 110.

The horizontal drive circuit 106 includes a shift register, for example, sequentially selects the column signal processing circuits 105 by sequentially outputting horizontal scanning pulses, and causes each of the column signal processing circuits 105 to output a pixel signal to the horizontal signal line 110.

The output circuit 107 performs signal processing on signals sequentially supplied from the column signal processing circuits 105 through the horizontal signal line 110, and outputs the processed signals. For example, the output circuit 107 performs only buffering in some cases, and performs black level adjustment, column variation correction, various digital signal processing, and the like in other cases. An input/output terminal 112 exchanges signals with the outside.

(Configuration Example of Pixel)

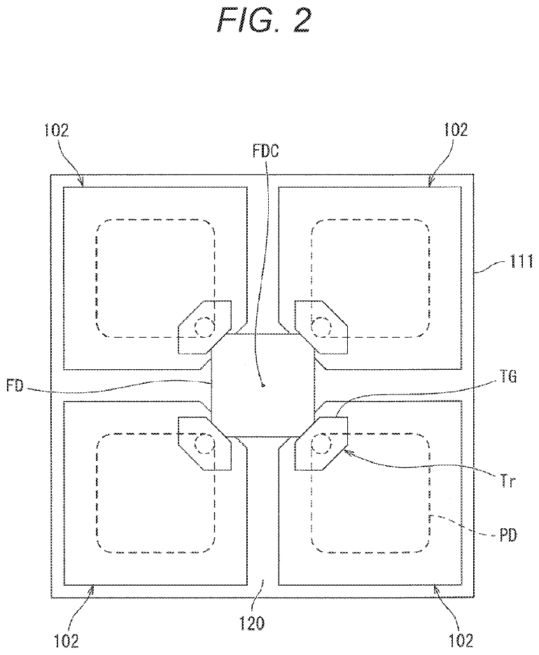

FIG. 2 is a plan view illustrating one example of a pixel sharing structure of the imaging device 100 according to First Embodiment of the present disclosure. As illustrated in FIG. 2, in the imaging device 100, for example, a total of four pixels 102 arranged two in each of the longitudinal direction and the lateral direction form one shared pixel structure. One shared pixel structure includes four photodiodes PD (one example of “photoelectric conversion unit” of present disclosure), four transfer transistors Tr (one example of “vertical transistor” of present disclosure), one shared floating diffusion FD (one example of “electric field holding unit” of present disclosure), one shared selection transistor (not illustrated), one shared reset transistor (not illustrated), and one shared amplification transistor (not illustrated).

The floating diffusion FD is arranged in a central part of the four pixels 102 included in one shared pixel structure. A gate electrode TG of the transfer transistor Tr is disposed in the vicinity of the floating diffusion FD. The gate electrodes TG of the four pixels 102 are disposed so as to surround one floating diffusion FD in plan view. A pixel isolation part 120 is provided on the outer periphery of each pixel 102. The pixel isolation part 120 includes, for example, an impurity diffusion layer of a conductivity type different from that of the semiconductor substrate 111, deep trench isolation, or the like.

In FIG. 2, the upper side in the vertical direction of the sheet surface is a front surface 111a side of the semiconductor substrate 111, and a multilayer wiring layer (not illustrated) including a plurality of wiring layers and an interlayer insulating film is provided. On the other hand, in FIG. 2, the lower side in the vertical direction of the sheet surface is the back surface side of the semiconductor substrate 111, and is a light incident surface on which light is incident, and an on-chip lens, a color filter, and the like (not illustrated) are provided. The imaging device 100 is a back-illuminated CMOS image sensor that photoelectrically converts light incident on the back surface side of the semiconductor substrate 111.

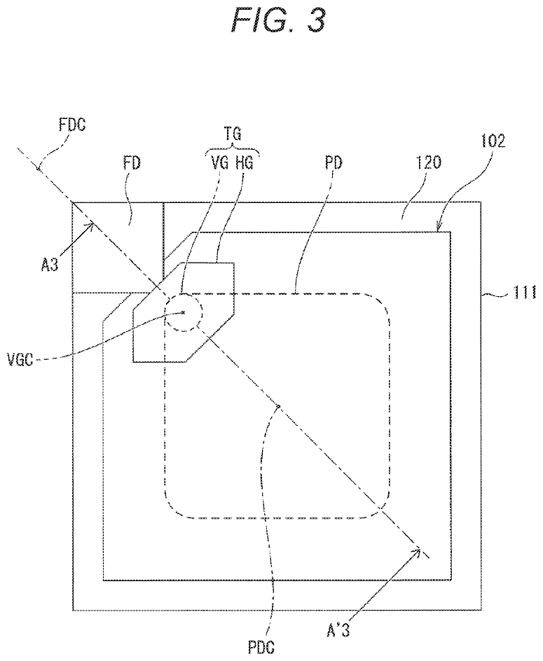

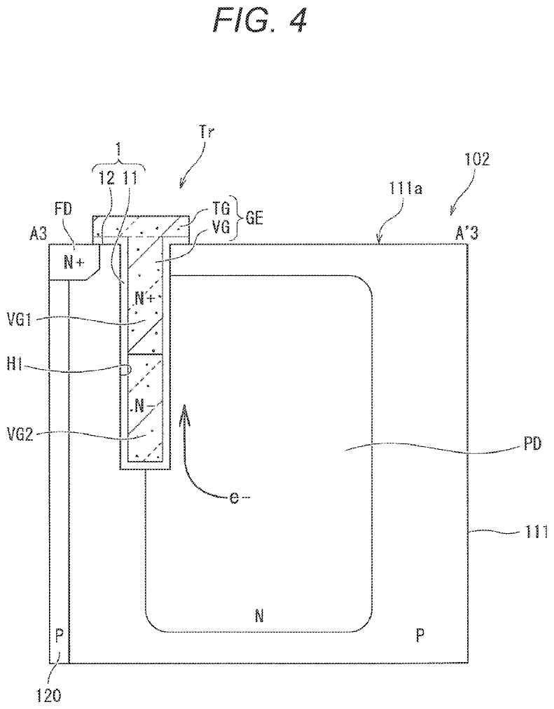

FIG. 3 is a plan view illustrating a configuration example of the pixel 102 according to First Embodiment of the present disclosure. FIG. 4 is a cross-sectional view illustrating a configuration example of the pixel 102 according to First Embodiment of the present disclosure. FIG. 4 schematically illustrates a cross section of FIG. 3 taken along line A3-A′3. Line A3-A′3 is a virtual line passing through a central part PDC of the photodiode PD, a central part VGC of a first gate electrode VG, and the central part FDC of the floating diffusion FD shared by the four pixels 102 in plan view. The semiconductor substrate 111 is, for example, a single crystal silicon substrate or a single crystal silicon layer formed on a substrate (not illustrated) by an epitaxial growth method. As illustrated in FIG. 4, the conductivity type of the semiconductor substrate 111 is, for example, P type.

As illustrated in FIGS. 3 and 4, the photodiode PD is provided inside the P-type semiconductor substrate 111. The photodiode PD includes, for example, an N-type impurity diffusion layer. The photodiode PD photoelectrically converts incident light incident on the back surface side of the semiconductor substrate 111 and accumulates obtained charge e⁻.

The transfer transistor Tr is provided from the inside of the semiconductor substrate 111 to the front surface 111a (one example of “first main surface” of present disclosure). The transfer transistor Tr is, for example, an N-type vertical transistor having the gate electrode TG and a gate insulating film 1 provided between the gate electrode TG and the semiconductor substrate 111, and having the photodiode PD as the source and the floating diffusion FD as the drain. The transfer transistor Tr transfers the charge e− generated by the photodiode PD from the photodiode PD to the floating diffusion FD.

The floating diffusion FD is provided on the front surface 111a side of the semiconductor substrate 111, and includes, for example, an N-type impurity diffusion layer. The floating diffusion FD holds the charge e⁻ transferred from the transfer transistor Tr.

The structure of the transfer transistor Tr will be described in more detail. The semiconductor substrate 111 is provided with a hole H1 opened to the front surface 111a side and is adjacent to the photodiode PD. The gate electrode TG includes a first gate electrode VG disposed in the hole H1 via a first gate insulating film 11 and extending in the longitudinal direction, and a second gate electrode HG extending in the lateral direction on a second gate insulating film 12 and connected to the first gate electrode VG.

Note that the longitudinal direction is a depth direction from the front surface 111a of the semiconductor substrate 111, in other words, a direction perpendicular to the front surface 111a. The lateral direction is a direction orthogonal to the depth direction of the semiconductor substrate 111, in other words, a direction parallel to the front surface 111a of the semiconductor substrate 111. Since the first gate electrode VG extends in the longitudinal direction, it may be referred to as a longitudinal gate electrode or a vertical gate electrode. Since the second gate electrode HG extends in the lateral direction, it may be referred to as a lateral gate electrode or a horizontal gate electrode.

The gate insulating film 1 includes the first gate insulating film 11 provided between an inner wall of the hole H1 and the first gate electrode VG, and a second gate insulating film 12 provided on the front surface 111a side of the semiconductor substrate 111 and in contact with the first gate insulating film 11. The second gate insulating film 12 is located between the front surface 111a of the semiconductor substrate 111 and the second gate electrode HG. The first gate insulating film 11 and the second gate insulating film 12 are, for example, a silicon oxide film formed by thermally oxidizing the semiconductor substrate 111. The first gate insulating film 11 and the second gate insulating film 12 are integrally formed.

The first gate electrode VG and the second gate electrode HG include, for example, polysilicon doped with an N-type impurity. The N-type impurity is, for example, phosphorus or arsenic. The first gate electrode VG and the second gate electrode HG are integrally formed.

The first gate electrode VG includes an N+ type first part VG1 and an N− type second part VG2 having an N-type impurity concentration lower than that of the first part VG1. For example, the N-type impurity concentration (N− concentration) in the second part VG2 is about 1/10 of the N-type impurity concentration (N+ concentration) in the first part VG1. As an example, the N+ concentration is 1×10¹⁹ cm⁻³ or more and less than 1×10²⁰ cm⁻³, and the N-concentration is 1×10¹⁸ cm⁻³ or more and less than 1×10¹⁹ cm⁻³.

The first part VG1 is located between the second part VG2 and the second gate electrode HG. The first part VG1 and the second part VG2 are connected to each other in the depth direction (i.e., direction orthogonal to front surface 111a) of the semiconductor substrate 111.

The first part VG1 and the second part VG2 are formed, for example, by multistage ion implantation of N-type impurities into polysilicon embedded in the hole H1. The multistage ion implantation is a method of continuously performing ion implantation having different acceleration energies. The first part VG1 and the second part VG2 can be separately formed in the polysilicon in the hole H1 by performing the multi-stage ion implantation in which the acceleration energy and the dose amount are adjusted such that the N-type impurity implanted in the region to be the first part VG1 has a higher concentration than the N-type impurity implanted in the region to be the second part VG2.

The second gate electrode HG is formed by ion-implanting an N-type impurity into polysilicon. The N-type impurity concentration (N+ concentration) in the second gate electrode HG is, for example, about the same as that of the first part VG1 of the first gate electrode VG, and is, for example, 1×10¹⁹ cm⁻ or more and less than 1×10²⁰ cm⁻³.

The charge e⁻ generated by photoelectric conversion in the photodiode PD is transferred in the longitudinal direction along the first gate electrode VG of the transfer transistor Tr, and then transferred in the horizontal direction along the second gate electrode HG, and reaches the floating diffusion FD. When the charge e⁻ is transferred from the photodiode PD to the floating diffusion FD, the charge e⁻ moves along a side surface of the first gate electrode VG so as to go around the first gate electrode VG.

Note that although not illustrated, a charge transfer channel may be provided in a region of the semiconductor substrate 111 facing the first gate electrode VG with the first gate insulating film 11 interposed therebetween. Furthermore, a charge transfer channel may be provided in a region of the semiconductor substrate 111 facing the second gate electrode HG with the second gate insulating film 12 interposed therebetween. The charge transfer channel includes, for example, a P-type impurity diffusion layer. By providing a charge transfer channel in the region described above, various characteristics (e.g., threshold voltage, withstand voltage in off state, or the like) of the transfer transistor can be adjusted to desired values.

(Potential Distribution)

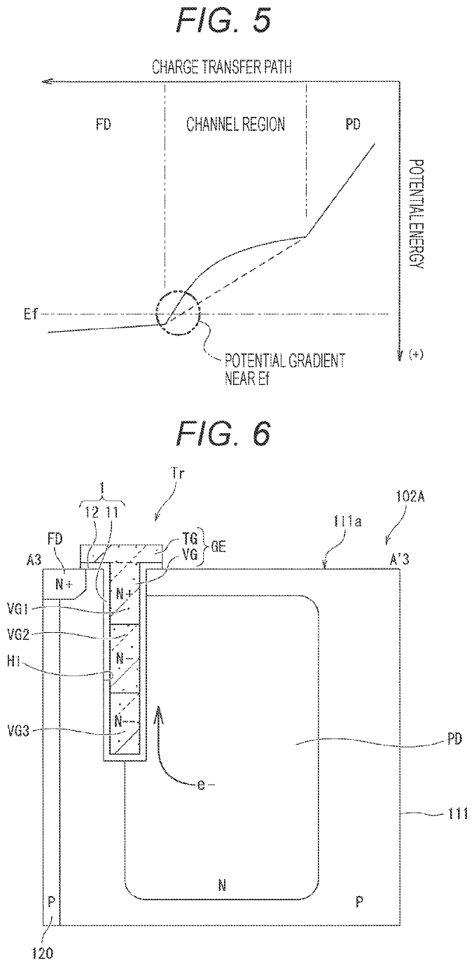

FIG. 5 is a graph schematically illustrating a potential distribution in the transfer path of the charge e− when the transfer transistor Tr is in an on state. In FIG. 5, the vertical axis represents potential energy, and the horizontal axis represents the transfer path of the charge e−. Furthermore, the broken line in FIG. 5 indicates a potential distribution of a mode (hereinafter, comparative example) in which the first gate electrode (vertical gate electrode) includes only N+ type polysilicon. The charge e− generated by photoelectric conversion in the photodiode PD move from the photodiode PD to the floating diffusion FD through a channel region formed along the gate electrode TG.

As illustrated in FIG. 4, gate electrode TG includes the first gate electrode VG extending in the longitudinal direction and the second gate electrode HG extending in the lateral direction. Furthermore, the first gate electrode VG includes the N+ type first part VG1 and the N− type second part VG2 connected to the first part VG1 in the longitudinal direction. Of the charge e− transferred from the photodiode PD to the floating diffusion FD, the charge e− moving in the longitudinal direction (from lower side to upper side in FIG. 4) along the first gate electrode VG passes through a channel region formed in the vicinity of the N− type second part VG2 and a channel region formed in the vicinity of the N+ type first part VG1 in this order.

In the transfer path in the longitudinal direction, the N− type second part VG2 is located on the photodiode PD side and the N+ type first part VG1 is located on the floating diffusion FD side. As a result, in the transfer path in the longitudinal direction, the potential gradient of the channel region decreases on the photodiode PD side and increases on the floating diffusion FD side as illustrated in FIG. 5. For example, on the floating diffusion FD side of the channel region, there is a Fermi level Ef at which the existence probability of electrons is 50%. The potential gradient near the Fermi level Ef where many electrons exist increases.

Since the potential gradient increases near the Fermi level Ef, movement of the charge e− existing near the Fermi level Ef to the floating diffusion FD side is promoted. Furthermore, movement of the charge e⁻ existing near the Fermi level Ef to the photodiode PD side is curbed because the potential gradient near the Fermi level Ef becomes a large and high barrier. As a result, when the gate of the transfer transistor Tr is switched from on to off, it is possible to prevent the charge e⁻ in the middle of transfer from returning to the photodiode PD side in the longitudinal direction (i.e., prevent charge e⁻ from being pumped up). It is possible to improve the transfer characteristic of the charge e⁻ in the longitudinal direction.

(Effects of First Embodiment)

As described above, the imaging device 100 according to First Embodiment of the present disclosure includes the semiconductor substrate 111 and the transfer transistor Tr provided on the semiconductor substrate 111. The semiconductor substrate 111 is provided with the hole H1 opened to the front surface 111a side. The transfer transistor Tr is a vertical transistor and includes the first gate electrode VG provided inside the hole H1 and the second gate electrode HG provided outside the hole H1 and connected to the first gate electrode VG. The first gate electrode VG includes the first part VG1 and the second part VG2 including a material having conductivity different from that of the first part VG1.

According to this, it is possible to provide a difference in conductivity between the first part VG1 and the second part VG2. For example, the first part VG1 can be an N+ type, and the second part VG2 can be an N− type. As a result, the potential gradient of the channel region (i.e., transfer path of charge e⁻) formed in the semiconductor substrate 111 can be varied. Even in a case where the transfer path of the charge e⁻ is long in the longitudinal direction like the transfer transistor Tr, it is possible to curb pumping up of the charge e⁻ by varying the potential gradient of the transfer path, and it is possible to improve the transfer characteristic of the charge e⁻.

### Second Embodiment

In First Embodiment above, it has been described that the first gate electrode VG of the transfer transistor Tr includes the N+ type first part VG1 and the N− type second part VG2. However, in the embodiment of the present disclosure, the configuration of the first gate electrode is not limited thereto. The first gate electrode may have a third part having conductivity different from conductivity of the first part and the second part.

FIG. 6 is a cross-sectional view illustrating a configuration example of a pixel 102A according to Second Embodiment of the present disclosure. Similarly to FIG. 4, FIG. 6 schematically illustrates a cross section of FIG. 3 taken along line A3-A′3. The pixel 102A illustrated in FIG. 6 is different from the pixel 102 illustrated in FIG. 4 in the configuration of a first gate electrode VG. As illustrated in FIG. 6, in the pixel 102A, the first gate electrode VG includes an N+ type first part VG1, an N− type second part VG2, and an N−− type third part VG3 that is located on the opposite side of the first part VG1 with the second part VG2 interposed therebetween and includes an N−− type semiconductor (e.g., polysilicon). The N+ type first part VG1, the N− type second part VG2, and the N−− type third part VG3 are arranged in this order from the front surface 111a of the semiconductor substrate 111 in the depth direction.

The N-type impurity concentration (N−− concentration) in the third part VG3 is lower than the N-type impurity concentration (N− concentration) in the second part VG2. For example, the N-concentration is 1×10¹⁷ cm⁻³ or more and less than 1×10¹⁸ cm⁻³. The N-type impurity concentration of the first gate electrode VG gradually decreases in the depth direction of the semiconductor substrate 111 in the order of N+, N−, and N−−.

In Second Embodiment, since the first gate electrode VG is divided into more levels of conductivity than in First Embodiment, it is possible to vary the potential gradient in a larger number of stages and more smoothly adjust the curve indicating the potential gradient. As a result, there is a possibility that the transfer characteristic of the charge e⁻ can be improved even further.

### Third Embodiment

In First Embodiment above, it has been described that the N+ type first part VG1 is located between the N− type second part VG2 and the second gate electrode HG, and the first part VG1 and the second part VG2 are connected to each other in the depth direction (i.e., longitudinal direction) of the semiconductor substrate 111. However, in the embodiment of the present disclosure, the configuration of the first gate electrode is not limited thereto. The first part and the second part of the first gate electrode may be connected to each other not in the depth direction of the semiconductor substrate but in a direction intersecting the depth direction of the semiconductor substrate.

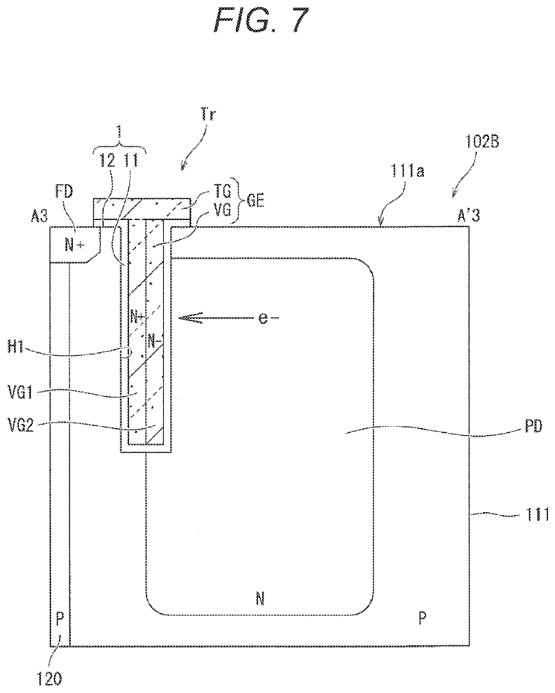

FIG. 7 is a cross-sectional view illustrating a configuration example of a pixel 102B according to Third Embodiment of the present disclosure. Similarly to FIG. 4, FIG. 7 schematically illustrates a cross section taken along line A3-A′3 in FIG. 3. In the pixel 102B illustrated in FIG. 7, a first part VG1 and a second part VG2 face each other in a direction (i.e., direction parallel to front surface 111a of the semiconductor substrate 111; lateral direction) orthogonal to the depth direction of a semiconductor substrate 111, and are connected to each other in the lateral direction.

According to this, among charge e⁻ transferred from a photodiode PD to a floating diffusion FD, the charge e⁻ moving in the lateral direction (from right side to left side in FIG. 7) along a first gate electrode VG passes through a channel region formed in the vicinity of the N-type second part VG2 and a channel region formed in the vicinity of the N+ type first part VG1 in this order.

In the transfer path in the lateral direction, the N− type second part VG2 is located on the photodiode PD side and the N+ type first part VG1 is located on the floating diffusion FD side. As a result, in the transfer path in the lateral direction, the potential gradient of the channel region decreases on the photodiode PD side and increases on the floating diffusion FD side as illustrated in FIG. 5.

Therefore, in Third Embodiment, when the gate of a transfer transistor Tr is switched from on to off, it is possible to prevent the charge e⁻ in the middle of transfer from returning to the photodiode PD side in the lateral direction (i.e., prevent charge e⁻ from being pumped up). It is possible to improve the transfer characteristic of the charge e⁻ in the lateral direction.

### Fourth Embodiment

In First Embodiment above, it has been described that the second part VG2 of the first gate electrode VG includes N− type polysilicon. However, in the embodiment of the present disclosure, the second part of the first gate electrode is not limited to the N− type polysilicon. The second part may include non-doped polysilicon.

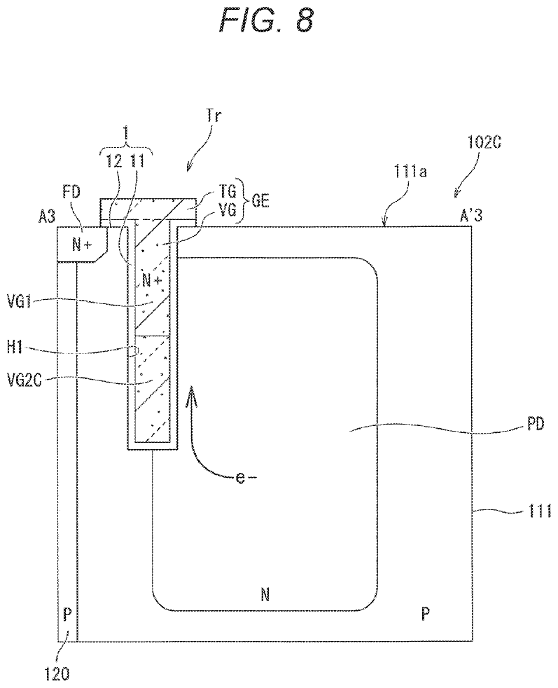

FIG. 8 is a cross-sectional view illustrating a configuration example of a pixel 102C according to Fourth Embodiment of the present disclosure. Similarly to FIG. 4, FIG. 8 schematically illustrates a cross section taken along line A3-A′3 in FIG. 3. In the pixel 102C illustrated in FIG. 8, a first gate electrode VG includes an N+ type first part VG1 and a non-doped second part VG2C. For example, the second part VG2C includes non-doped polysilicon. In the pixel 102C, the first part VG1 is located between the second part VG2C and a second gate electrode HG. The first part VG1 and the second part VG2C are connected to each other in the longitudinal direction.

In a transfer path of charge e⁻ moving in the longitudinal direction along the first gate electrode VG, the non-doped second part VG2C is located on the photodiode PD side and the N+ type first part VG1 is located on the floating diffusion FD side. As a result, in the transfer path in the longitudinal direction, the potential gradient of the channel region decreases on the photodiode PD side and increases on the floating diffusion FD side as illustrated in FIG. 5. Therefore, similarly to First Embodiment, Fourth Embodiment, too, can curb pumping up of the charge e⁻ in the middle of transfer in the longitudinal direction. It is possible to improve the transfer characteristic of the charge e⁻ in the longitudinal direction.

### Fifth Embodiment

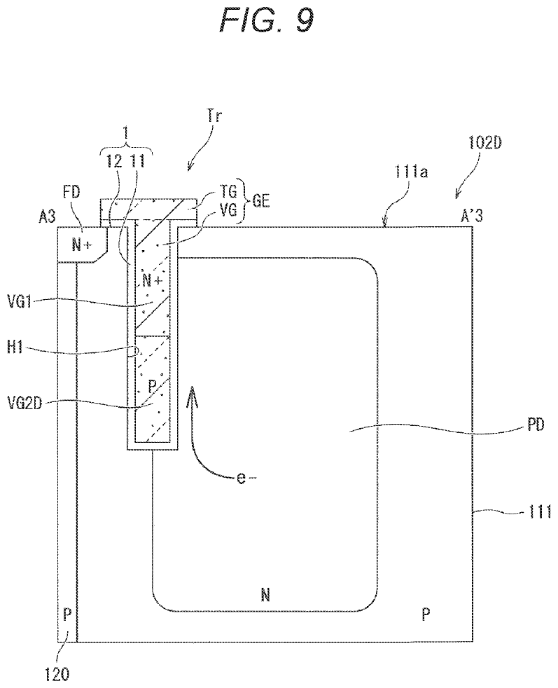

In the embodiment of the present disclosure, the second part may include P-type polysilicon. FIG. 9 is a cross-sectional view illustrating a configuration example of a pixel 102D according to Fifth Embodiment of the present disclosure. Similarly to FIG. 4, FIG. 9 schematically illustrates a cross section taken along line A3-A′3 in FIG. 3. In the pixel 102D illustrated in FIG. 9, a first gate electrode VG includes an N+ type first part VG1 and a P-type second part VG2D. For example, the second part VG2D includes P-type polysilicon. The P-type impurity is phosphorus or arsenic. In the pixel 102D, the first part VG1 is located between the second part VG2D and a second gate electrode HG. The first part VG1 and the second part VG2D are connected to each other in the longitudinal direction.

In a transfer path of charge e⁻ moving in the longitudinal direction along the first gate electrode VG, the P-type second part VG2D is located on the photodiode PD side and the N+ type first part VG1 is located on the floating diffusion FD side. As a result, in the transfer path in the longitudinal direction, the potential gradient of the channel region decreases on the photodiode PD side and increases on the floating diffusion FD side as illustrated in FIG. 5. Therefore, similarly to First Embodiment, Fifth Embodiment, too, can curb pumping up of the charge e⁻ in the middle of transfer in the longitudinal direction. It is possible to improve the transfer characteristic of the charge e⁻ in the longitudinal direction.

### Sixth Embodiment

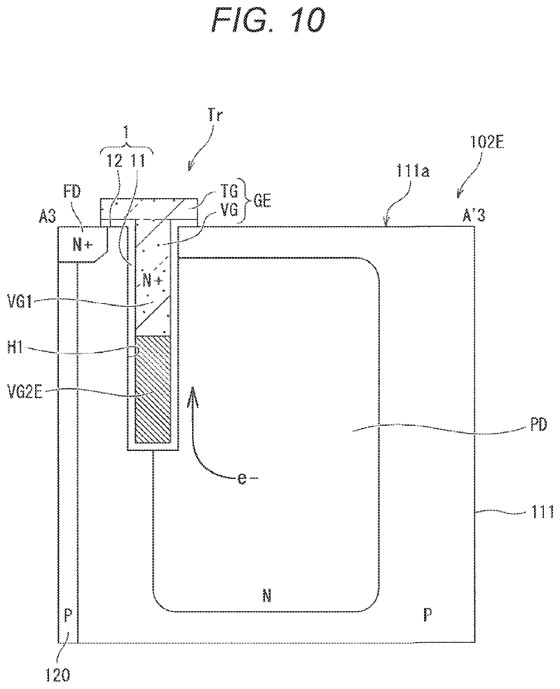

In the embodiment of the present disclosure, the second part may include metal. FIG. 10 is a cross-sectional view illustrating a configuration example of a pixel 102E according to Sixth Embodiment of the present disclosure. Similarly to FIG. 4, FIG. 10 schematically illustrates a cross section taken along line A3-A′3 in FIG. 3. In the pixel 102E illustrated in FIG. 10, a first gate electrode VG includes an N+ type first part VG1 and a second part VG2E including metal. For example, the second part VG2E includes aluminum (Al), tungsten silicide (WSi), titanium silicide (TiSi), cobalt silicide (CoSi), nickel silicide (NiSi), or a laminated metal obtained by laminating one or more of these materials.

In the pixel 102E, the first part VG1 is located between the second part VG2E and a second gate electrode HG. The first part VG1 and the second part VG2E are connected to each other in the depth direction (i.e., direction orthogonal to front surface 111a) of a semiconductor substrate 111.

In a transfer path of charge e⁻ moving in the longitudinal direction along the first gate electrode VG, the second part VG2E including metal is located on the photodiode PD side and the N+ type first part VG1 is located on the floating diffusion FD side. There is a work function difference between the metal included in the second part VG2E and the semiconductor substrate 111. For this reason, in the transfer path in the longitudinal direction, the potential gradient of the channel region decreases on the photodiode PD side and increases on the floating diffusion FD side as illustrated in FIG. 5. Therefore, similarly to First Embodiment, Sixth Embodiment, too, can curb pumping up of the charge e⁻ in the middle of transfer in the longitudinal direction. It is possible to improve the transfer characteristic of the charge e⁻ in the longitudinal direction.

### Other Embodiments

While the present disclosure has been described above with reference to the embodiments and the modifications, it should not be understood that the description and the drawings forming a part of this disclosure limit the present disclosure. Various alternative embodiments, examples, and operation techniques will be apparent to those skilled in the art from this disclosure. It is a matter of course that the technology according to the present disclosure (present technology) includes various embodiments and the like that are not described herein.

For example, First to Sixth Embodiments above describe modes in which one gate electrode GE has one first gate electrode VG extending in the longitudinal direction. However, in the embodiment of the present disclosure, the number of first gate electrodes VG included in one gate electrode GE is not limited to one, and may be plural. In such a mode too, since at least one or more of the plurality of first gate electrodes VG has the first part VG1 and the second part VG2 (or VG2C, VG2D, VG2E) including a material having conductivity different from that of the first part VG1, it is possible to curb pumping up of the charge e⁻ and to improve the transfer characteristic of the charge e⁻.

Furthermore, the configuration of Third Embodiment may be applied to each of Second and Fourth to Sixth Embodiments described above. Specifically, in the first gate electrode VG of the pixel 102B illustrated in FIG. 7, the third part VG3 including an N− type semiconductor, the second part VG2 including an N− type semiconductor, and the first part VG1 including an N+ type semiconductor may be arranged in this order from the photodiode PD toward the floating diffusion FD side (from right side to left side in FIG. 7). Alternatively, the second part VG2 illustrated in FIG. 7 may be replaced with any one of the second part VG2C (see FIG. 8) including a non-doped semiconductor, the second part VG2D (see FIG. 9) including a P-type semiconductor, or the second part VG2E including metal. As described above, the present technology can include at least one of various omissions, substitutions, and changes of components without departing from the gist of the above-described embodiments. Furthermore, the effect described in the present specification is merely an illustration and is not restrictive. Hence, other effects can be obtained.

### Example of Application to Electronic Device

The technology according to the present disclosure (present technology) can be applied to various electronic devices including an imaging system such as a digital still camera and a digital video camera, a mobile phone having an imaging function, and other devices having an imaging function, for example.

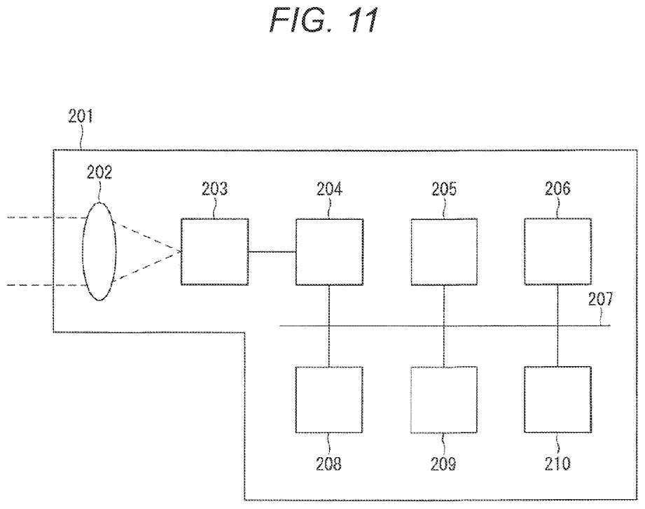

FIG. 11 is a block diagram illustrating a configuration example of an imaging device mounted on an electronic device. As illustrated in FIG. 11, an electronic device 201 includes an optical system (one example of “optical component” of present disclosure) 202, an image pickup element 203, and a digital signal processor (DSP; one example of “signal processing circuit” of present disclosure) 204, is configured by connecting the DSP 204, a display device 205, an operation system 206, a memory 208, a recording device 209, and a power supply system 210 via a bus 207, and is capable of capturing a still image and a moving image.

The optical system 202 includes one or more lenses, guides image light (incident light) from a subject to the image pickup element 203, and forms an image on a light receiving surface (sensor unit) of the image pickup element 203.

As the image pickup element 203, the imaging device 100 including any one or more of the above-described pixels 102, 102A, 102B, 102C, 102D, and 102E in the pixel region 103 is applied. In the image pickup element 203, electrons are accumulated for a certain period according to an image formed on the light receiving surface through the optical system 202. Then, a signal corresponding to the electrons accumulated in the image pickup element 203 is supplied to the DSP 204.

The DSP 204 performs various types of signal processing on the signal from the image pickup element 203 to acquire an image, and temporarily stores data of the image in the memory 208. The image data stored in the memory 208 is recorded in the recording device 209 or supplied to the display device 205 to display an image. Furthermore, the operation system 206 receives various operations by the user and supplies an operation signal to each block of the electronic device 201. The power supply system 210 supplies power necessary for driving each block of the electronic device 201.

In the electronic device 201 configured as described above, the above-described imaging device 100 is applied as the image pickup element 203. As a result, it is possible to improve the transfer characteristic of the charge e⁻ in the image pickup element 203, and thus, it is possible to improve the performance of the electronic device 201.

### Example of Application to Endoscopic Surgery System

The technology according to the present disclosure (present technology) can be applied to various products. For example, the technology according to the present disclosure may be applied to an endoscopic surgery system.

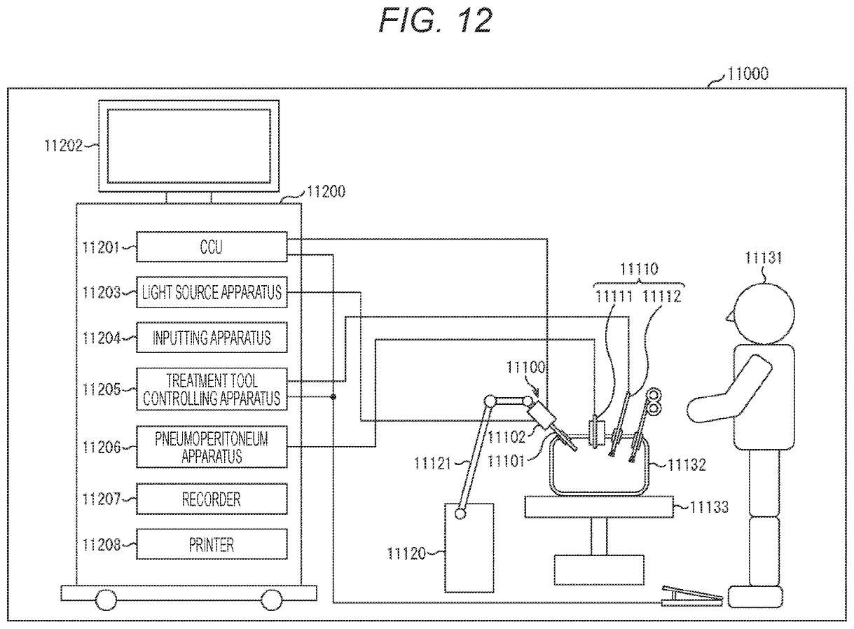

FIG. 12 is a diagram illustrating one example of a schematic configuration of an endoscopic surgery system to which the technology according to the present disclosure (present technology) can be applied.

FIG. 12 illustrates a state in which a surgeon (medical doctor) 11131 is performing a surgery on a patient 11132 on a patient bed 11133 using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

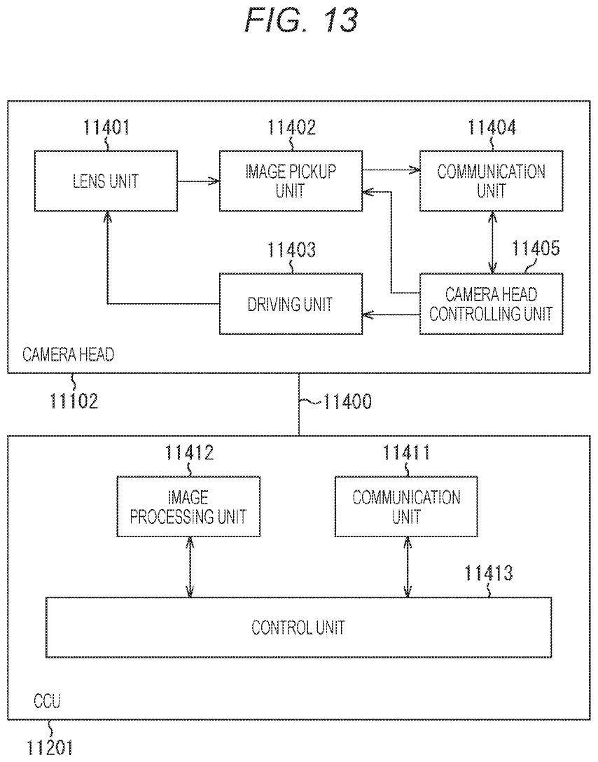

FIG. 13 is a block diagram illustrating one example of a functional configuration of the camera head 11102 and the CCU 11201 illustrated in FIG. 12.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure can be applied has been described above. The technology according to the present disclosure can be applied to the endoscope 11100, the image pickup unit 11402 of the camera head 11102, the image processing unit 11412 of the CCU 11201, and the like, among the configurations described above. Specifically, the imaging device 100 described above can be applied to the image pickup unit 10402. By applying the technology according to the present disclosure to the endoscope 11100, the image pickup unit 11402 of the camera head 11102, the image processing unit 11412 of the CCU 11201, and the like, a clearer surgical region image can be obtained, so that the surgeon can reliably confirm the surgical region. Furthermore, by applying the technology according to the present disclosure to the endoscope 11100, the image pickup unit 11402 of the camera head 11102, the image processing unit 11412 of the CCU 11201, and the like, it is possible to obtain a surgical region image with lower latency, and thus, it is possible to perform treatment with a feeling similar to that in a case where the surgeon performs tactile observation of the surgical region.

Note that while an endoscopic surgery system has been described herein as one example, the technology according to the present disclosure may be applied to a microscope surgery system and the like, for example.

### Example of Application to Movable Body

The technology according to the present disclosure (present technology) can be applied to various products. For example, the technology according to the present disclosure may be implemented as a device mounted on any type of movable bodies including a car, an electric car, a hybrid electric car, a motorcycle, a bicycle, a personal mobility, an airplane, a drone, a ship, a robot, and the like.

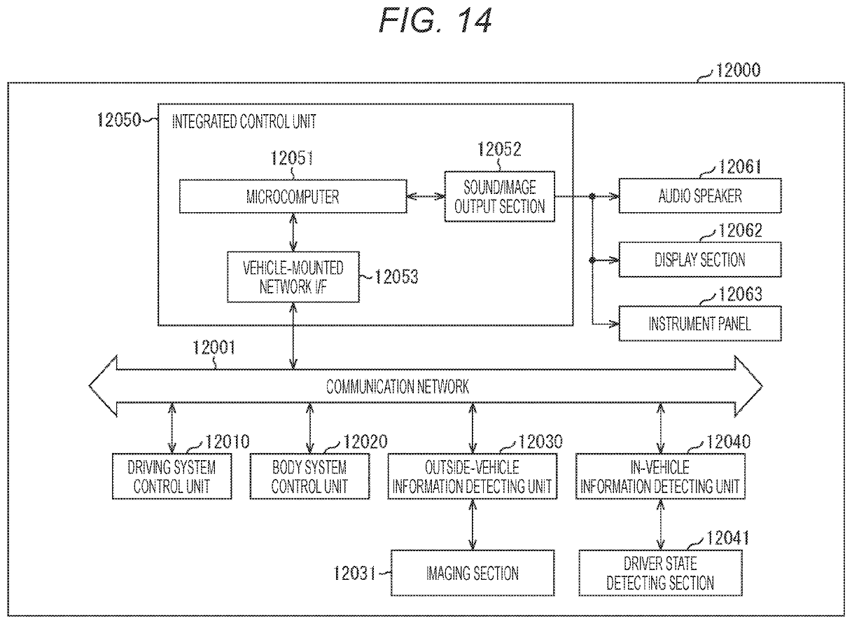

FIG. 14 is a block diagram illustrating a schematic configuration example of a vehicle control system which is one example of a movable body control system to which the technology according to the present disclosure can be applied.

The vehicle control system 12000 includes a plurality of electronic control units connected to each other via a communication network 12001. In the example depicted in FIG. 14, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 14, an audio speaker 12061, a display section 12062, and an instrument panel 12063 are illustrated as the output device. The display section 12062 may, for example, include at least one of an on-board display and a head-up display.

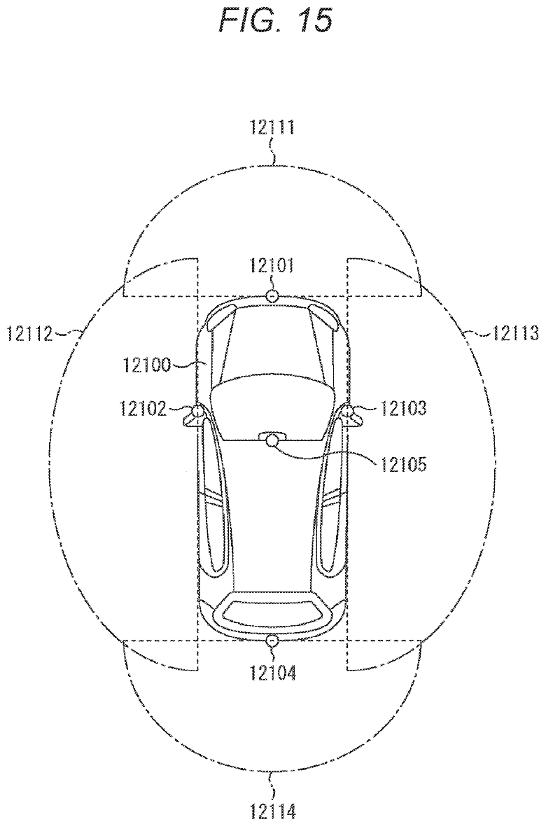

FIG. 15 is a diagram depicting an example of the installation position of the imaging section 12031.

In FIG. 15, a vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper part of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. Images of the front acquired by the imaging sections 12101 and 12105 are mainly used to detect a preceding vehicle or a pedestrian, an obstacle, a traffic light, a traffic sign, a lane, or the like.

Note that FIG. 15 depicts one example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Hereinabove, one example of the vehicle control system to which the technology according to the present disclosure can be applied has been described. The technology according to the present disclosure is applicable to the imaging section 12031 or the like among the configurations described above. Specifically, the imaging device 100 described above can be applied to the imaging section 12031. By applying the technology according to the present disclosure to the imaging section 12031, a captured image that is easier to see can be obtained, so that driver fatigue can be reduced.

Note that the present disclosure can also be configured in the following manner.

(1)

An imaging device including
a semiconductor substrate, and
a vertical transistor provided on the semiconductor substrate, in which:
the semiconductor substrate is provided with a hole opened to a first main surface side;
the vertical transistor includes
a first gate electrode provided inside the hole, and
a second gate electrode provided outside the hole and connected to the first gate electrode; and
the first gate electrode includes
a first part, and
a second part including a material having conductivity different from conductivity of the first part.

(2)

The imaging device according to (1) above, in which
the first part is located between the second part and the second gate electrode.

(3)

The imaging device according to (1) above, in which
the first part and the second part face each other in a direction parallel to the first main surface.

(4)

The imaging device according to any one of (1) to (3) above, in which
each of the first part and the second part includes a semiconductor of a first conductivity type, and
an impurity concentration of the first conductivity type in the second part is lower than an impurity concentration of the first conductivity type in the first part.

(5)

The imaging device according to (4) above, in which
the first gate electrode further includes a third part that is located on an opposite side of the first part with the second part interposed therebetween and includes a semiconductor of a first conductivity type, and
an impurity concentration of the first conductivity type in the third part is lower than an impurity concentration of the first conductivity type in the second part.

(6)

The imaging device according to any one of (1) to (3) above, in which
the first part includes a semiconductor of a first conductivity type, and
the second part includes a non-doped semiconductor.

(7)

The imaging device according to any one of (1) to (3) above, in which
the first part includes a semiconductor of a first conductivity type, and
the second part includes a semiconductor of a second conductivity type.

(8)

The imaging device according to any one of (1) to (3) above, in which
the first part includes a semiconductor of a first conductivity type, and
the second part includes metal.

(9)

The imaging device according to any one of (1) to (8) above further including
a photoelectric conversion unit provided on the semiconductor substrate, and
a charge holding unit that is provided on the semiconductor substrate and holds charge generated in the photoelectric conversion unit, in which
the vertical transistor is used as a transfer transistor that transfers charge from the photoelectric conversion unit to the charge holding unit.

(10)

An electronic device including:
an optical component;
an imaging device on which light transmitted through the optical component is incident; and
a signal processing circuit that processes a signal output from the imaging device, in which:
the imaging device includes
a semiconductor substrate, and
a vertical transistor provided on the semiconductor substrate;
the semiconductor substrate is provided with a hole opened to a first main surface side;
the vertical transistor includes
a first gate electrode provided inside the hole, and
a second gate electrode provided outside the hole and connected to the first gate electrode; and
the first gate electrode includes
a first part, and
a second part including a material having conductivity different from conductivity of the first part.

### REFERENCE SIGNS LIST

1 Gate insulating film
11 First gate insulating film
12 Second gate insulating film
100 Imaging device
102, 102A, 102B, 102C, 102D, 102E Pixel
103 Pixel region
104 Vertical drive circuit
105 Column signal processing circuit
106 Horizontal drive circuit
107 Output circuit
108 Control circuit
109 Vertical signal line
110 Horizontal signal line
111 Semiconductor substrate
111a Front surface
112 Input/output terminal
120 Pixel isolation part
201 Electronic device
202 Optical system
203 Image pickup element
205 Display device
206 Operation system
207 Bus
208 Memory
209 Recording device
210 Power supply system
10402, 12031 Image pickup unit
11000 Endoscopic surgery system
11100 Endoscope
11101 Lens barrel
11102 Camera head
11110 Surgical tool
11111 Pneumoperitoneum tube
11112 Energy device
11120 Supporting arm apparatus
11131 Surgeon
11132 Patient
11133 Patient bed
11200 Cart
11201 Camera control unit (CCU)
11202 Display device
11203 Light source apparatus
11204 Inputting apparatus
11205 Treatment tool controlling apparatus
11206 Pneumoperitoneum apparatus
11207 Recorder
11208 Printer
11400 Transmission cable
11401 Lens unit
11402 Image pickup unit
11403 Driving unit
11404, 11411 Communication unit
11405 Camera head controlling unit
11412 Image processing unit
11413 Control unit
12000 Vehicle control system
12001 Communication network
12010 Driving system control unit
12020 Body system control unit
12030 Outside-vehicle information detecting unit
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101, 12102, 12103, 12104, 12105 Imaging section
12111, 12112, 12113, 12114 Imaging range
CCU11201 Image pickup unit (camera head)
DSP Image pickup element
FD Floating diffusion
FDC, PDC, VGCCentral part
GE Gate electrode
H1 Hole
HG Second gate electrode
PD Photodiode
TG Gate electrode
Tr Transfer transistor
VG First gate electrode
VG1 First part
VG2, VG2C, VG2D, VG2E Second part
VG3 Third part

What is claimed is:

1. An imaging device comprising
a semiconductor substrate, and
a vertical transistor provided on the semiconductor substrate, wherein:
the semiconductor substrate is provided with a hole opened to a first main surface side;
the vertical transistor includes
a first gate electrode provided inside the hole, and
a second gate electrode provided outside the hole and connected to the first gate electrode; and
the first gate electrode includes
a first part, and
a second part including a material having conductivity different from conductivity of the first part.

2. The imaging device according to claim 1, wherein
the first part is located between the second part and the second gate electrode.

3. The imaging device according to claim 1, wherein
the first part and the second part face each other in a direction parallel to the first main surface.

4. The imaging device according to claim 1, wherein
each of the first part and the second part includes a semiconductor of a first conductivity type, and
an impurity concentration of the first conductivity type in the second part is lower than an impurity concentration of the first conductivity type in the first part.

5. The imaging device according to claim 4, wherein
the first gate electrode further includes a third part that is located on an opposite side of the first part with the second part interposed therebetween and includes a semiconductor of a first conductivity type, and
an impurity concentration of the first conductivity type in the third part is lower than an impurity concentration of the first conductivity type in the second part.

6. The imaging device according to claim 1, wherein
the first part includes a semiconductor of a first conductivity type, and
the second part includes a non-doped semiconductor.

7. The imaging device according to claim 1, wherein
the first part includes a semiconductor of a first conductivity type, and
the second part includes a semiconductor of a second conductivity type.

8. The imaging device according to claim 1, wherein
the first part includes a semiconductor of a first conductivity type, and
the second part includes metal.

9. The imaging device according to claim 1 further comprising
a photoelectric conversion unit provided on the semiconductor substrate, and
a charge holding unit that is provided on the semiconductor substrate and holds charge generated in the photoelectric conversion unit, wherein
the vertical transistor is used as a transfer transistor that transfers charge from the photoelectric conversion unit to the charge holding unit.

10. An electronic device, comprising:
an optical component;
an imaging device on which light transmitted through the optical component is incident; and
a signal processing circuit that processes a signal output from the imaging device, wherein:
the imaging device includes
a semiconductor substrate, and
a vertical transistor provided on the semiconductor substrate;
the semiconductor substrate is provided with a hole opened to a first main surface side;
the vertical transistor includes
a first gate electrode provided inside the hole, and
a second gate electrode provided outside the hole and connected to the first gate electrode; and
the first gate electrode includes
a first part, and
a second part including a material having conductivity different from conductivity of the first part.
